(19) United States
(12) Patent Application Publication
(10) Pub. No.: US 2025/0006775 A1
(43) Pub. Date: Jan. 2, 2025

(54) SEMICONDUCTOR ELEMENT AND SEMICONDUCTOR DEVICE

(71) Applicant: Rohm Co., Ltd., Kyoto-shi (JP)

(72) Inventor: Hiroaki MATSUBARA, Kyoto-shi (JP)

(21) Appl. No.: 18/883,501

(22) Filed: Sep. 12, 2024

Related U.S. Application Data
(63) Continuation of application No. PCT/JP2023/006742, filed on Feb. 24, 2023.

(30) Foreign Application Priority Data
Mar. 17, 2022 (JP) 2022-042701

(51) Int. Cl. H01L 23/00; H01L 23/31; H01L 23/495

(52) U.S. Cl. CPC H01L 28/10; H01L 23/3107; H01L 23/49513; H01L 23/49575; H01L 24/48; H01L 2224/48137; H01L 2224/48245; H01L 2924/1206

(57) ABSTRACT

A semiconductor element includes a main body having an obverse surface and a reverse surface facing away from each other in a first direction and a plurality of electrodes disposed on the obverse surface and electrically conducting to the main body. The main body has a first side surface facing in the second direction x. The first side surface includes a first edge that is farthest from the reverse surface. The main body has a second side surface connected to the first edge and located between the first side surface and the obverse surface in the first direction z. The second side surface overlaps with the reverse surface as viewed in the first direction z. The surface roughness of the first side surface differs from that of the second side surface.

### TECHNICAL FIELD

The present disclosure relates to a semiconductor element and a semiconductor device including the semiconductor element.

### BACKGROUND ART

The semiconductor device disclosed in JP-A-2016-207714 has a control element (controller) and a drive element (gate driver) mounted therein. The semiconductor device drives a switching element such as an IGBT. The semiconductor device is therefore used in an inverter circuit or the like.

In the semiconductor device, the power supply voltage supplied to the drive element is equal to or greater than the voltage applied to the switching element, so that the power supply voltage supplied to the control element and the power supply voltage supplied to the drive element differ from each other. This results in a difference between the voltage applied to the control element and its conduction path and the voltage applied to the drive element and its conduction path.

In the semiconductor device, therefore, an insulating element is interposed in the electric signal transmission path between the control element and the drive element to insulate the control element and its conductive path and the drive element and its conductive path from each other. This prevents electric breakdown of the control element and the drive element.

In the semiconductor device, the insulating element is bonded to a die pad. Such bonding is performed using a bonding layer made of a paste containing metal particles. During the bonding, the bonding layer, which has fluidity, may rise onto the insulating element. When the bonding layer rises excessively, it may adhere to the wire conductively bonded to the insulating element. This can cause a short circuit between the die pad and the wire.

### BRIEF DESCRIPTION OF THE DRAWINGS

FIG. 1 is a plan view of a semiconductor element according to a first embodiment of the present disclosure.

FIG. 2 is a sectional view taken along line II-II in FIG. 1.

FIG. 3 is a partial enlarged view of FIG. 2.

FIG. 4 is a sectional view illustrating a manufacturing step of the semiconductor element shown in FIG. 1.

FIG. 5 is a sectional view illustrating a manufacturing step of the semiconductor element shown in FIG. 1.

FIG. 6 is a sectional view of a semiconductor element according to a variation of the first embodiment of the present disclosure.

FIG. 7 is a partial enlarged view of FIG. 6.

FIG. 8 is a plan view of a semiconductor device according to a first embodiment of the present disclosure.

FIG. 9 is a plan view corresponding to FIG. 8, in which the sealing resin is shown in its outline only.

FIG. 10 is a front view of the semiconductor device shown in FIG. 8.

FIG. 11 is a left side view of the semiconductor device shown in FIG. 8.

FIG. 12 is a right side view of the semiconductor device shown in FIG. 8.

FIG. 13 is a sectional view taken along line XIII-XIII in FIG. 9.

FIG. 14 is a sectional view taken along line XIV-XIV in FIG. 9.

FIG. 15 is a partial enlarged view of FIG. 9.

FIG. 16 is a sectional view taken along line XVI-XVI in FIG. 15.

FIG. 17 is a partially enlarged sectional view of the semiconductor device shown in FIG. 8, in which the configuration of the bonding layer differs from that shown in FIG. 16.

FIG. 18 is a plan view of a semiconductor device according to a second embodiment of the present disclosure, in which the sealing resin is shown in its outline only.

FIG. 19 is a sectional view taken along line XIX-XIX in FIG. 18.

FIG. 20 is a plan view of a semiconductor element according to a second embodiment of the present disclosure.

FIG. 21 is a sectional view taken along line XXI-XXI in FIG. 20.

FIG. 22 is a partial enlarged view of FIG. 21, showing the second edge of a second side surface and the nearby portion.

FIG. 23 is a partial enlarged view of FIG. 21, showing the first edge of a first side surface and the nearby portion.

FIG. 24 is a sectional view of a semiconductor element according to a variation of the second embodiment of the present disclosure.

FIG. 25 is a partial enlarged view of FIG. 24.

FIG. 26 is a plan view of a semiconductor element according to a variation of a third embodiment of the present disclosure.

FIG. 27 is a sectional view taken along line XXVII-XXVII in FIG. 26.

### DETAILED DESCRIPTION OF EMBODIMENTS

Modes for carrying out the present disclosure will be described below based on the accompanying drawings.

### First Embodiment (Semiconductor Element A10)

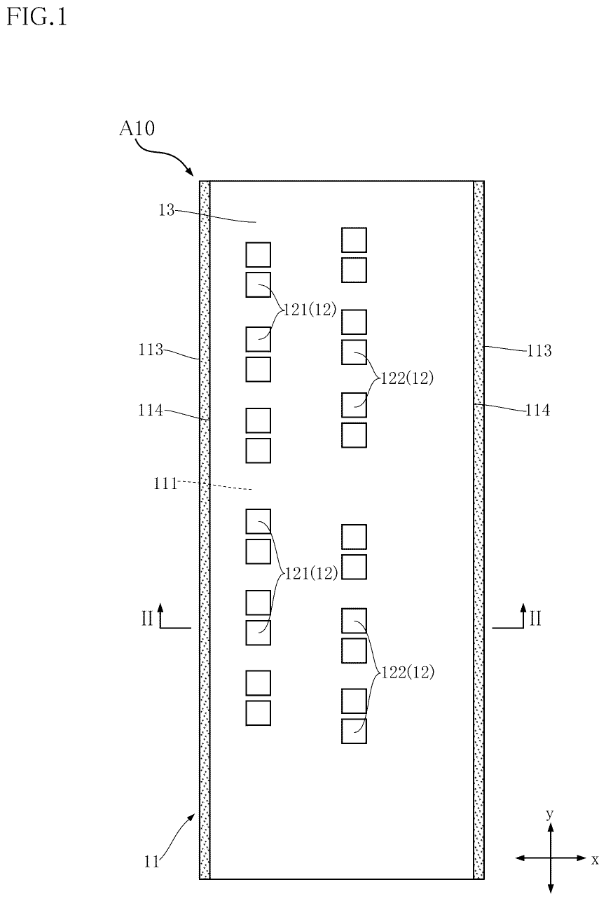

A semiconductor element A10 according to a first embodiment of the present disclosure will be described based on FIGS. 1 to 3. The semiconductor element A10 includes a main body 11, a plurality of electrodes 12, and a passivation film 13.

In the explanation of the semiconductor element A10 and the semiconductor device B10 described later, an example of the direction that is normal to the obverse surface 111 of the main body 11, describe later, is referred to as the “first direction z” for convenience. An example of a direction orthogonal to the first direction z is referred to as the “second direction x”. An example of the direction orthogonal to the first direction z and the second direction x is referred to as the “third direction y”.

The semiconductor element A10 transmits electric signals such as PWM (Pulse Width Modulation) control signals in an insulated state. The semiconductor element A10 is of an inductive type. One example of the inductive semiconductor element A10 is an isolation transformer. The isolation transformer includes two inductively coupled inductors (coils) to realize transmission of electric signals in an insulated state. The two inductors include a transmitting-side inductor and a receiving-side inductor. Each of the two inductors is stacked in the first direction z. A dielectric layer made of, for example, silicon dioxide (SiO₂) is disposed between the transmitting-side inductor and the receiving-side inductor. The dielectric layer provides electrical insulation between the transmitting-side inductor and the receiving-side inductor. Alternatively, the semiconductor element A10 may be of a capacitive type. One example of the capacitive semiconductor element A10 is a capacitor.

As shown in FIG. 1, the main body 11 is rectangular as viewed in the first direction z. The dimension of the main body 11 in the third direction y is greater than the dimension of the main body 11 in the second direction x. Thus, as viewed in the first direction z, the main body 11 has a rectangular shape elongated in the third direction y. The main body 11 includes a semiconductor substrate 11A and a semiconductor layer 11B. The semiconductor substrate 11A supports the semiconductor layer 11B. The composition of the semiconductor substrate 11A includes, for example, silicon (Si). The semiconductor layer 11B is laminated on the semiconductor substrate 11A. The semiconductor layer 11B contains the above-described two inductors and the above-described dielectric layer. The semiconductor layer 11B further includes a redistribution wiring layer electrically conducting to the two inductors.

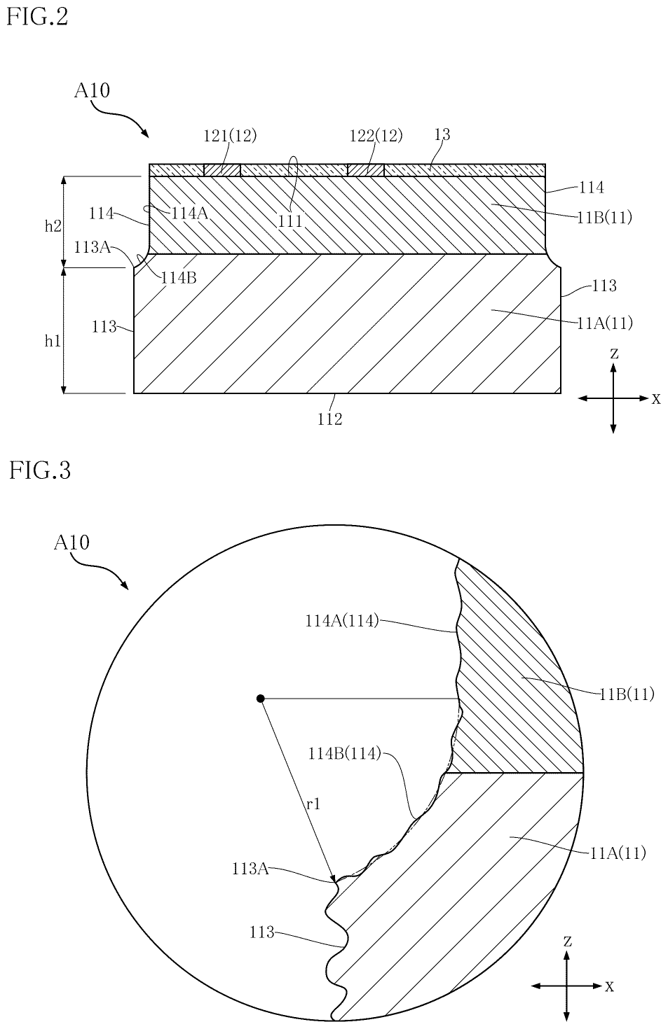

As shown in FIG. 2, the main body 11 has an obverse surface 111, a reverse surface 112, two first side surfaces 113, and two second side surfaces 114. The obverse surface 111 and the reverse surface 112 face away from each other in the first direction z.

As shown in FIGS. 1 and 2, the two first side surfaces 113 face away from each other in the second direction x. The two second side surface 114 face away from each other in the second direction x. The two second side surfaces 114 are connected to the two first side surfaces 113, respectively. Each of the two first side surfaces 113 and the two second side surfaces 114 extends in the third direction y. Only one of the two first side surfaces 113 and the second side surface 114 connected to the first side surface 113 will be described below.

As shown in FIG. 2, the first side surface 113 has a first edge 113A that is farthest from the reverse surface 112. The second side surface 114 is connected to the first edge 113A. The second side surface 114 is located between the first side surface 113 and the obverse surface 111 in the first direction z. As viewed in the first direction z, the second side surface 114 overlaps with the reverse surface 112.

As shown in FIG. 2, the second side surface 114 includes a first region 114A and a second region 114B. The first region 114A faces in the second direction x. The second region 114B is connected to the first edge 113A and the first region 114A. The second region 114B is curved toward the reverse surface 112.

In the semiconductor element A10, the dimension h1 of the first side surface 113 in the first direction z is greater than the dimension h2 of the second side surface 114 in the first direction z, as shown in FIG. 2. The dimension h1 is equal to or greater than 50% of the dimension of the main body 11 in the first direction z. Thus, the dimension h1 differs from the dimension h2.

As shown in FIG. 3, the surface roughness of the second side surface 114 is smaller than the surface roughness of the first side surface 113. Thus, the surface roughness of the first side surface 113 differs from the surface roughness of the second side surface 114. Further, the surface roughness of each of the first side surface 113 and the second side surface 114 is greater than the surface roughness of the reverse surface 112.

Assuming that the surface roughness of the second region 114B is zero (two-dot chain lines shown in FIG. 3) in the cross section in which the first direction z and the second direction x define the in-plane direction, the second region 114B forms a curved surface with a radius of curvature r1, as shown in FIG. 3.

As shown in FIGS. 1 and 2, the electrodes 12 are disposed on the obverse surface 111 of the main body 11. The electrodes 12 electrically conduct to the redistribution wiring layer, which is a part of the semiconductor layer 11B of the main body 11. The electrodes 12 include a plurality of first electrodes 121 and a plurality of second electrodes 122. The first electrodes 121 are arranged along the third direction y. The second electrodes 122 are located on one side in the second direction x with respect to the first electrodes 121. The second electrodes 122 are arranged along the third direction y. The composition of the electrodes 12 includes, for example, aluminum (Al).

As shown in FIG. 2, the passivation film 13 is layered on the obverse surface 111 of the main body 11. As shown in FIG. 1, the passivation film 13 surrounds the electrodes 12 as viewed in the first direction z. The passivation film 13 is an insulator. The composition of the passivation film 13 includes, for example, silicon nitride (Si₃N₄).

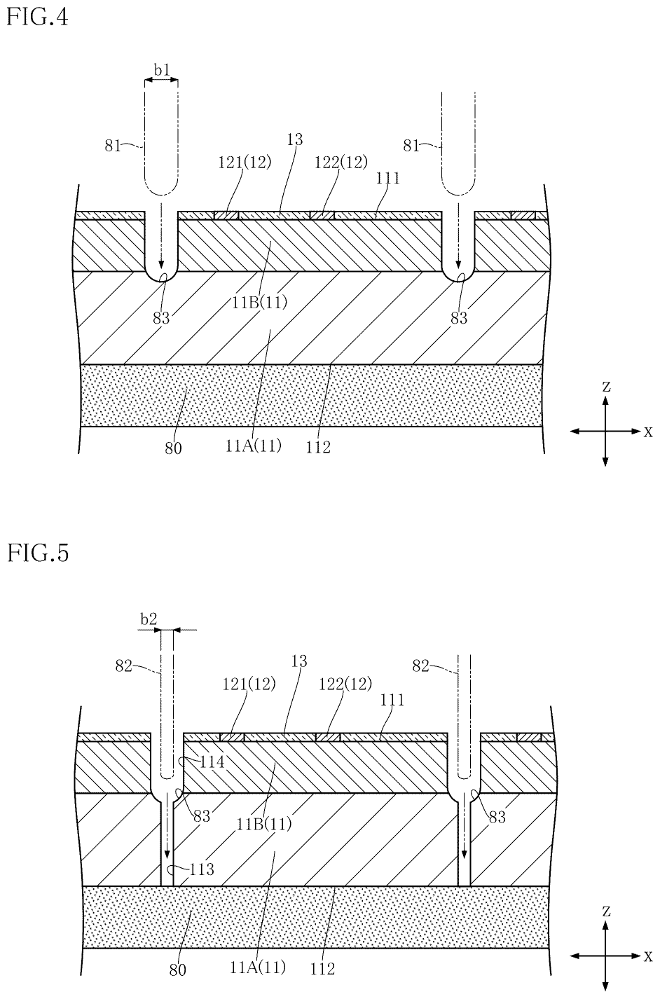

Next, a method for forming the first side surface 113 and the second side surface 114 of the main body 11 of the semiconductor element A10 will be described based on FIGS. 4 and 5. Prior to forming these surfaces, the main body 11 including the semiconductor substrate 11A and the semiconductor layer 11B, the electrodes 12, and the passivation film 13 are formed.

First, a tape 80 is attached to the reverse surface 112 of the main body 11 as shown in FIG. 4. The tape 80 is a dicing tape. Next, portions of each of the main body 11 and the passivation film 13 are removed with a first blade 81 having a width b1 to form a plurality of grooves 83. The width b1 is not less than 25 μm and not more than 40 μm. The grooves 83 are formed from the obverse surface 111 toward the reverse surface 112 in the first direction z. The grooves 83 are formed in a grid pattern along the second direction x and the third direction y.

Next, as shown in FIG. 5, the main body 11 is cut with a second blade 82 having a width b2. The width b2 is smaller than the width b1 of the first blade 81. The width b2 is not less than 15 μm and not more than 25 μm. Further, the surface roughness of the second blade 82 is greater than the surface roughness of the first blade 81. During the cutting using the first blade 81, the second blade 82 is moved through each of the grooves 83 and then moved in the first direction z until the second blade 82 comes into contact with the tape 80. Finally, the tape 80 is removed from the reverse surface 112. Through the above process, the formation of the first side surface 113 and the second side surface 114 of the main body 11 is completed.

### Variation (Semiconductor Element A11):

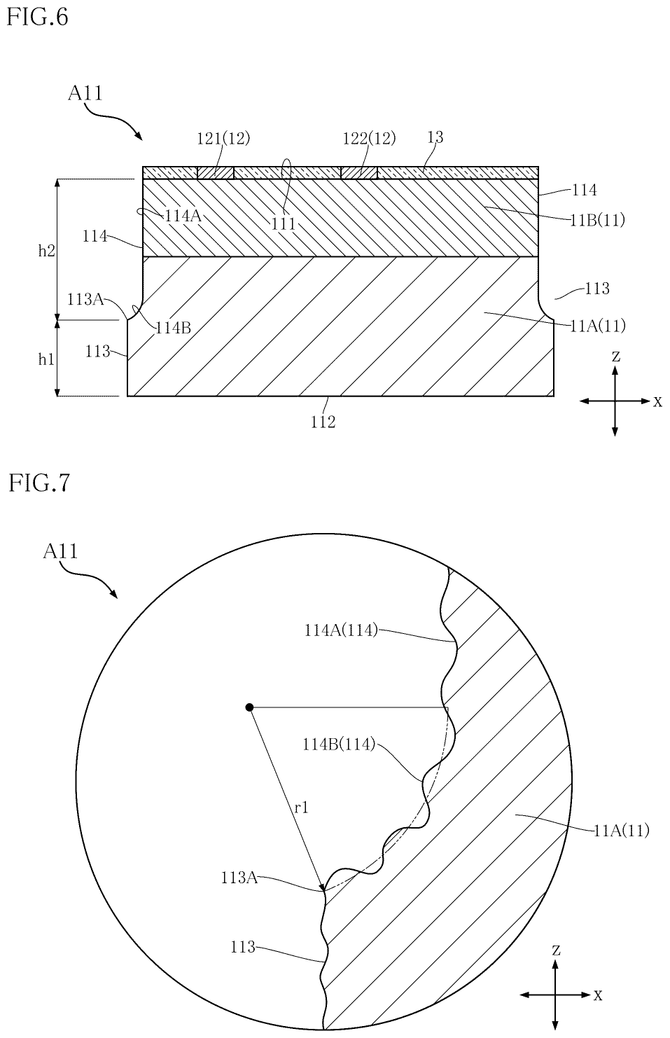

Next, a semiconductor element A11, which is a variation of the semiconductor element A10, will be described based on FIGS. 6 and 7. The sectional position of FIG. 6 corresponds to (or generally corresponds to) the sectional position of FIG. 2.

As shown in FIG. 6, the semiconductor element A11 differs from the semiconductor element A10 in the configurations of the first side surface 113 and the second side surface 114. The dimension h2 of the second side surface 114 in the first direction z is greater than the dimension h1 of the first side surface 113 in the first direction z.

As shown in FIG. 7, the surface roughness of the second side surface 114 is greater than the surface roughness of the first side surface 113. In the semiconductor element A11 as well, assuming that the surface roughness of the second region 114B is zero (two-dot chain lines shown in FIG. 7) in the cross section in which the first direction z and the second direction x define the in-plane direction, the second region 114B forms a curved surface with a radius of curvature r1.

### First Embodiment (Semiconductor Device B10)

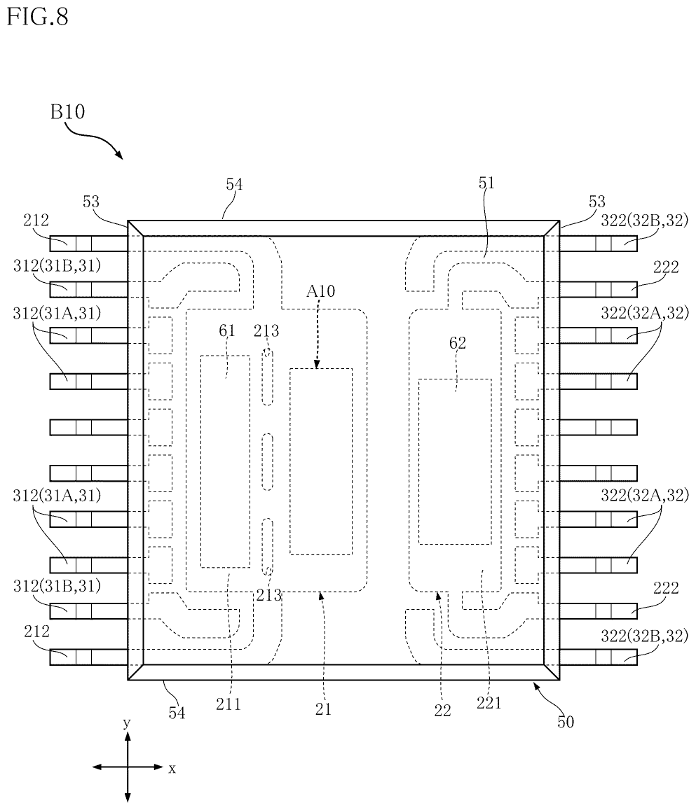

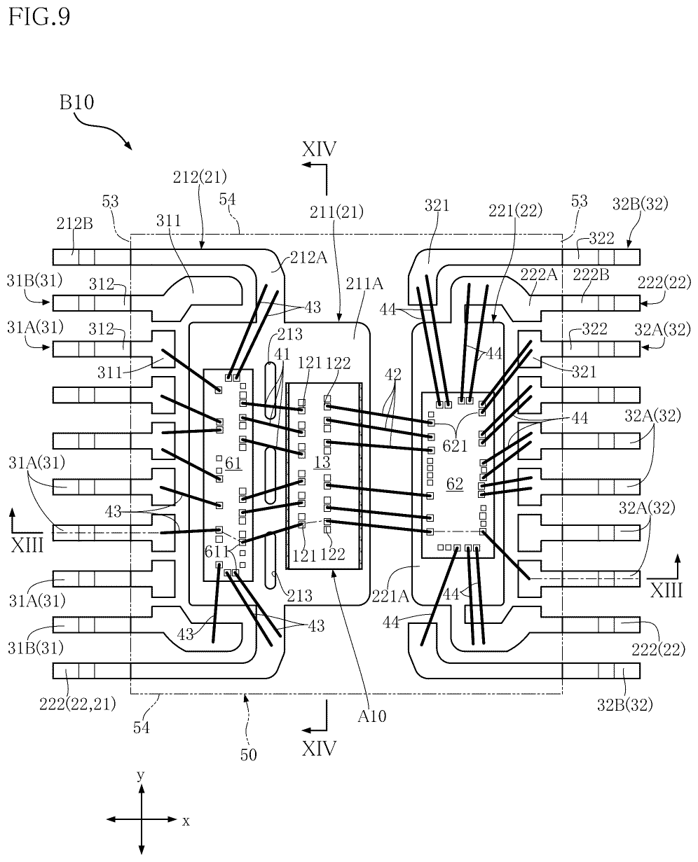

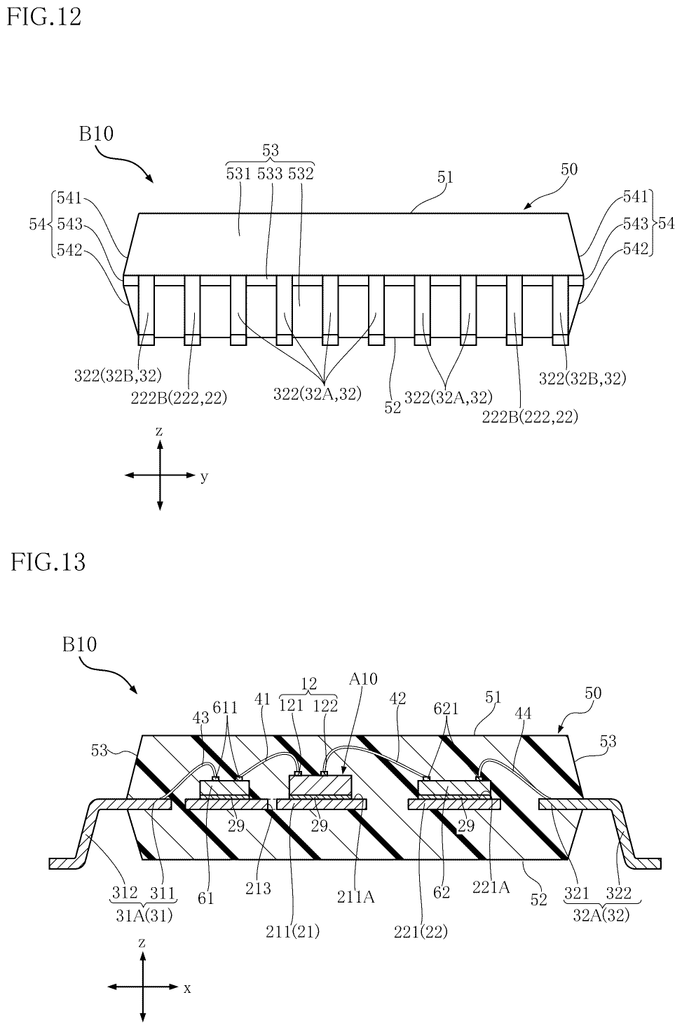

A semiconductor device B10 according to a first embodiment of the present disclosure will be described based on FIGS. 8 to 17. The semiconductor device B10 includes a control element 61, a drive element 62, the semiconductor element A10, a first die pad 21, a second die pad 22, a bonding layer 29, a plurality of first terminals 31, a plurality of second terminals 32, and a sealing resin 50. The semiconductor device B10 further includes a plurality of first wires 41, a plurality of second wires 42, a plurality of third wires 43, and a plurality of fourth wires 44. The semiconductor device B10 is to be surface-mounted on a wiring board of an inverter device of, for example, an electric vehicle or a hybrid vehicle. The package type of the semiconductor device B10 is the SOP (small outline package). However, the package type of the semiconductor device B10 is not limited to the SOP. In FIG. 9, the sealing resin 50 is shown in its outline only for the convenience of understanding. In FIG. 9, the outline of the sealing resin 50 is shown by imaginary lines (two-dot chain lines).

The control element 61, the drive element 62, and the semiconductor element A10 are the core components for the functions of the semiconductor device B10. In the semiconductor device B10, the control element 61, the drive element 62, and the semiconductor element A10 are individual elements. The drive element 62 is located opposite to the control element 61 with respect to the semiconductor element A10 in the second direction x. As viewed in the first direction z, each of the control element 61 and the drive element 62 has a rectangular shape elongated in the third direction y.

The control element 61 controls the drive element 62. The control element 61 includes a circuit for converting electric signals inputted from other semiconductor devices into PWM control signals, a transmission circuit for transmitting the PWM control signals to the drive element 62, and a receiving circuit for receiving electric signals from the drive element 62.

The drive element 62 drives switching elements located outside the semiconductor device B10. The switching elements are, for example, IGBTs (Insulated Gate Bipolar Transistors) or MOSFETs (Metal-Oxide-Semiconductor Field-Effect Transistors). The drive element 62 includes a receiving circuit for receiving PWM control signals, a circuit for driving the switching elements based on the PWM control signals, and a transmission circuit for transmitting electric signals to the control element 61. Examples of the electric signals include an output signal from a temperature sensor disposed near the motor.

The voltage applied to the control element 61 and the voltage applied to the drive element 62 differ from each other. Thus, there is a potential difference between the control element 61 and the drive element 62. In the semiconductor device B10, the voltage applied to the drive element 62 is higher than the voltage applied to the control element 61. Further, in the semiconductor device B10, the power supply voltage supplied to the drive element 62 is higher than the power supply voltage supplied to the control element 61.

In the semiconductor device B10, therefore, the first circuit that includes the control element 61 as its component and the second circuit that includes the drive element 62 as its component are the insulated from each other by semiconductor element A10. The semiconductor element A10 is electrically connected to the first circuit and the second circuit. The components of the first circuit include the first die pad 22, the first terminals 31, the first wires 41 and the third wires 43, described later, in addition to the control element 61. The components of the second circuit include the second die pad 22, the second terminals 32, the second wires 42 and the fourth wires 44, described later, in addition to the drive element 62. The first circuit and the second circuit have different potentials. In the semiconductor device B10, the potential of the second circuit is higher than the potential of the first circuit. In this state, the semiconductor element A10 relays signals between the first circuit and the second circuit. For example, in an inverter device for an electric vehicle or a hybrid vehicle, the voltage applied to the ground of the drive element 62 may transiently become 600 V or higher while the voltage applied to the ground of the control element 61 is about 0 V.

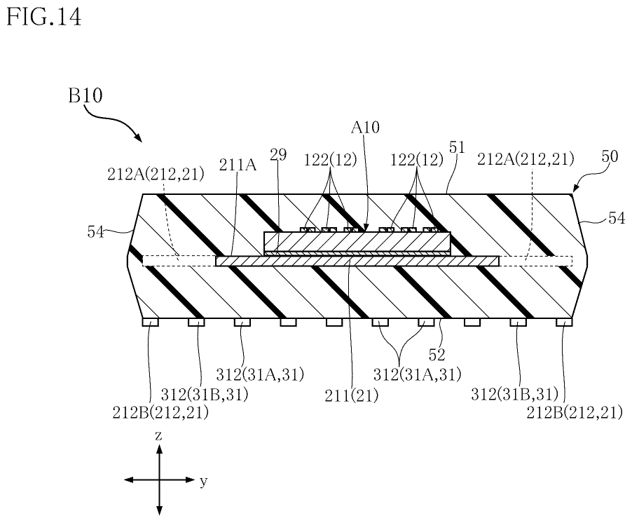

As shown in FIGS. 9 and 13, the control element 61 has a plurality of electrodes 611. The electrodes 611 are provided on the upper surface of the control element 61 (the surface facing in the same direction as the first mount surface 211A of the first pad portion 211 of the first die pad 21, described later). The composition of the electrodes 611 includes, for example, aluminum. The electrodes 611 electrically conduct to the circuit formed in the control element 61.

As shown in FIGS. 9 and 13, the drive element 62 has a plurality of electrodes 621. The electrodes 621 are provided on the upper surface of the drive element 62 (the surface facing in the same direction as a second mount surface 221A of a second pad portion 221 of the second die pad 22, described later). The composition of the electrodes 621 includes, for example, aluminum. The electrodes 621 electrically conduct to the circuit formed in the drive element 62.

As shown in FIGS. 9 and 13, the semiconductor element A10 is located between the control element 61 and the drive element 62 in the second direction x. Thus, the control element 61 is located opposite to the drive element 62 with respect to the semiconductor element A10 in the second direction x. The first electrodes 121 of the semiconductor element A10 are located closer to the control element 61 than to the drive element 62 in the second direction x. The second electrodes 122 of the semiconductor element A10 are located opposite to the control element 61 with respect to the first electrodes 121 in the second direction x.

The first die pad 21, the second die pad 22, the first terminals 31, and the second terminals 32 form conduction paths between the wiring board on which the semiconductor device B10 is mounted and the control element 61, the drive element 62 and the semiconductor element A10. The first die pad 21, the second die pad 22, the first terminals 31, and the second terminals 32 are formed from a same lead frame. The lead frame includes copper in its composition.

As shown in FIGS. 8 and 9, the first die pad 21 and the second die pad 22 are spaced apart from each other in the second direction x. In the semiconductor device B10, the control element 61 is mounted on the first die pad 21, and the drive element 62 is mounted on the second die pad 22. The voltage applied to the second die pad 22 differs from the voltage applied to the first die pad 21. In the semiconductor device B10, the voltage applied to the second die pad 22 is higher than the voltage applied to the first die pad 21.

As shown in FIG. 9, the first die pad 21 has the first pad portion 211 and two first suspension lead portions 212. The control element 61 is mounted on the first pad portion 211. As shown in FIGS. 13 and 14, the first pad portion 211 has a first mounting surface 221A facing in the first direction z. The control element 61 is bonded to the first mounting surface 211A via a bonding layer 29. The bonding layer 29 is made of a paste containing metal particles. The composition of the metal particles is, for example, silver (Ag). Therefore, the bonding layer 29 is a conductor. Alternatively, the bonding layer 29 may be solder. The first pad portion 211 is covered with the sealing resin 50. The thickness of the first pad portion 211 is, for example, equal to or greater than 150 μm and equal to or less than 200 μm.

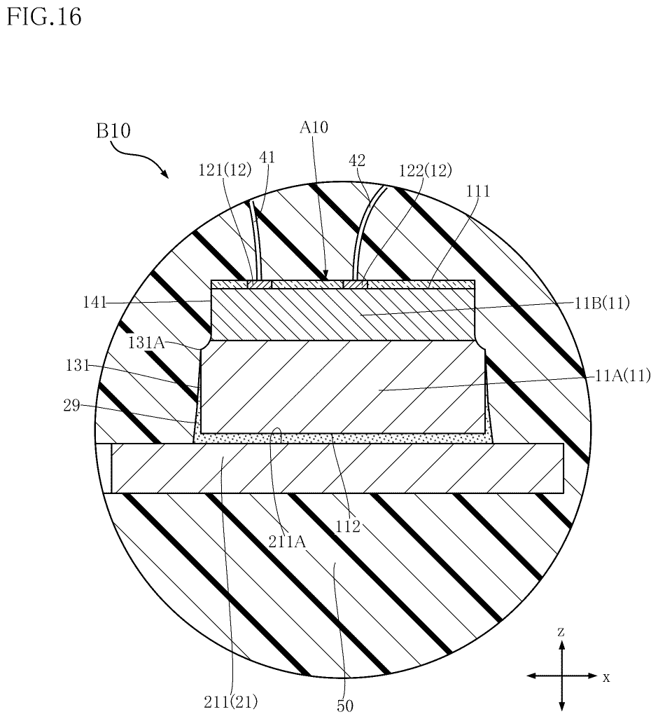

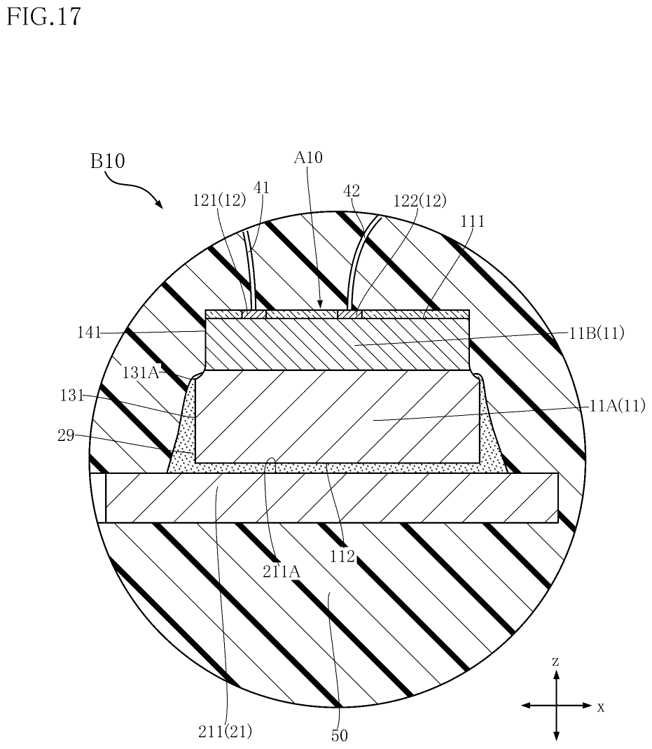

As shown in FIG. 16, the reverse surface 112 of the main body 11 of the semiconductor element A10 faces the first mounting surface 211A of the first die pad 21. The main body 11 is bonded to the first mounting surface 211A via a bonding layer 29. The bonding layer 29 is in contact with the first side surface 113 of the main body 11. The bonding layer 29 reaches the first edge 113A of the first side surface 113. That is, the bonding layer 29 is in contact with the first edge 113A as well.

In the semiconductor device B10, the bonding layer 29 may be in contact with the first side surface 113 and the second side surface 114 of the main body 11 as shown in FIG. 17. In this case, the bonding layer 29 straddles the first edge 113A of the first side surface 113.

As shown in FIGS. 9 and 13, the first pad portion 211 is formed with a plurality of through-holes 213. Each of the through-holes 213 penetrates the first pad portion 211 in the first direction z and extends in the third direction y. As viewed in the first direction z, at least one of the through-holes 213 is located between the control element 61 and semiconductor element A10. The through-holes 213 are arranged along the third direction y.

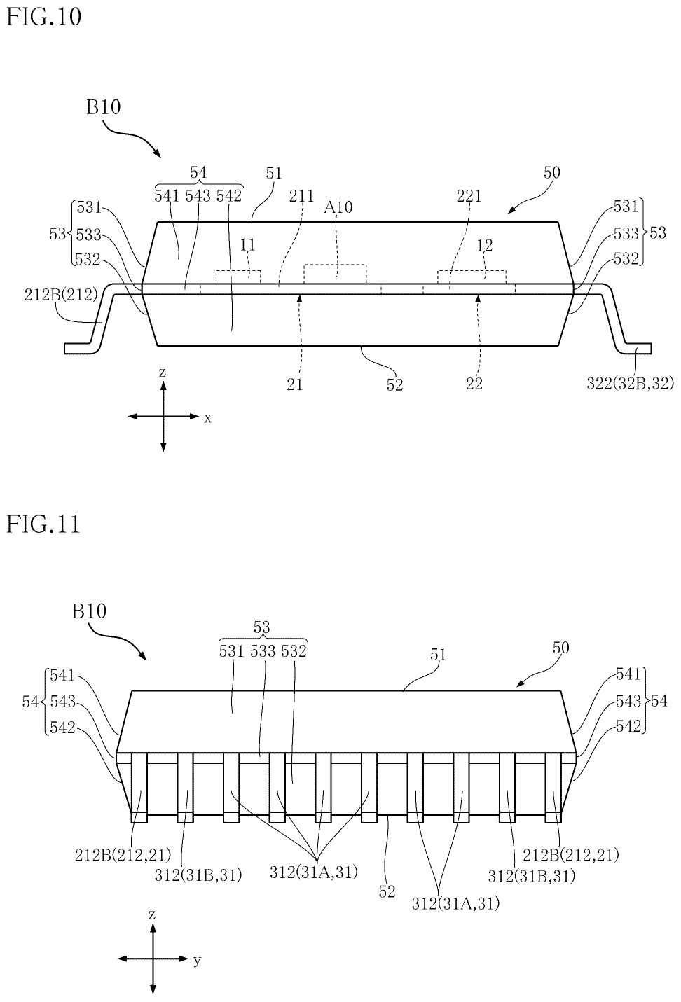

As shown in FIG. 9, the two first suspension lead portions 212 are connected to opposite ends in the third direction y of the first pad portion 211. Each of the two first suspension lead portions 212 has a covered portion 212A and an exposed portion 212B. The covered portion 212A is connected to the first pad portion 211 and covered with the sealing resin 50. The covered portion 212A includes a section extending in the second direction x. The exposed portion 212B is connected to the covered portion 212A and exposed from the sealing resin 50. As viewed in the first direction z, the exposed portion 212B extends in the second direction x. As shown in FIG. 10, the exposed portion 212B is bent into a gull-wing shape as viewed in the third direction y. The surface of the exposed portion 212B may be plated with, for example, tin (Sn).

As shown in FIG. 9, the second die pad 22 has the second pad portion 221 and two second suspension lead portions 222. The drive element 62 is mounted on the second pad portion 221. As shown in FIG. 13, the second pad portion 221 has a second mount surface 221A facing in the first direction z. The drive element 62 is bonded to the second mount surface 221A via a bonding layer 29. The second pad portion 221 is covered with the sealing resin 50. The thickness of the second pad portion 221 is, for example, equal to or greater than 150 μm and equal to or less than 200 μm. The area of the second pad portion 221 is smaller than the area of the first pad portion 211 of the first die pad 21. As viewed in the second direction x, the second pad portion 221 overlaps with the first pad portion 211.

As shown in FIG. 9, the two second suspension lead portions 222 extend outward from opposite ends in the third direction y of the second pad portion 221. Each of the two second suspension lead portions 222 has a covered portion 222A and an exposed portion 222B. The covered portion 222A is connected to the second pad portion 221 and covered with the sealing resin 50. The covered portion 222A includes a section extending in the second direction x. The exposed portion 222B is connected to the covered portion 222A and exposed from the sealing resin 50. As viewed in the first direction z, the exposed portion 222B extends in the second direction x. As shown in FIG. 10, the exposed portion 222B is bent into a gull-wing shape as viewed in the third direction y. The surface of the exposed portion 222B may be plated with, for example, tin.

As shown in FIGS. 8 and 9, the first terminals 31 are located opposite to the drive element 62 with respect to the semiconductor element A10 in the second direction x. The first terminals 31 are arranged along the third direction y. At least one of the first terminals 31 electrically conducts to the control element 61 via a third wire 43. The first terminals 31 are located between two first suspension lead portions 212 of the first die pad 21 in the third direction y. The first terminals 31 include a plurality of first intermediate terminals 31A and two first-side terminals 31B. The two first-side terminals 31B are located on opposite sides of the first intermediate terminals 31A in the third direction y.

As shown in FIGS. 9 and 13, each of the first terminals 31 has a covered portion 311 and an exposed portion 312. The covered portion 311 is covered with the sealing resin 50. The dimension of the covered portion 311 of each of the two first-side terminals 31B in the second direction x is greater than the dimension of the covered portion 311 of each of the first intermediate terminals 31A in the second direction x.

As shown in FIGS. 9 and 13, the exposed portion 312 is connected to the covered portion 311 and exposed from the sealing resin 50. As viewed in the first direction z, the exposed portion 312 extends in the second direction x. The exposed portion 312 is bent into a gull-wing shape as viewed in the third direction y. The shape of the exposed portion 312 is the same as that of the exposed portion 212B of each of the two first suspension lead portions 212 of the first die pad 21. The surface of the exposed portion 312 may be plated with, for example, tin.

As shown in FIGS. 8 and 9, the second terminals 32 are located opposite to the control element 61 with respect to the semiconductor element A10 in the second direction x. The second terminals 32 are arranged along the third direction y. At least one of the second terminals 32 electrically conducts to the drive element 62 via a fourth wire 44. The second terminals 32 include a plurality of second intermediate terminals 32A and two second-side terminals 32B. The two second suspension lead portion 222 of the second die pad 22 are located on opposite sides of the second intermediate terminals 32A in the third direction y. The two second-side terminals 32B are located to flank the second intermediate terminals 32A and the two second suspension lead portions 222 in the third direction y.

As shown in FIGS. 9 and 13, each of the second terminals 32 has a covered portion 321 and an exposed portion 322. The covered portion 321 is covered with the sealing resin 50. The dimension of the covered portion 321 of each of the two second-side terminals 32B in the second direction x is greater than the dimension of the covered portion 321 of each of the second intermediate terminals 32A in the second direction x.

As shown in FIGS. 9 and 13, the exposed portion 322 is connected to the covered portion 321 and exposed from the sealing resin 50. As viewed in the first direction z, the exposed portion 322 extends in the second direction x. As shown in FIG. 10, the exposed portion 322 is bent into a gull-wing shape as viewed in the third direction y. The shape of the exposed portion 322 is the same as that of the exposed portion 222B of each of the two second suspension lead portions 222 of the second die pad 22. The surface of the exposed portion 322 may be plated with, for example, tin.

The first wires 41, the second wires 42, the third wires 43 and the fourth wires 44 form, together with the first die pad 21, the second die pad 22, the first terminals 31 and the second terminals 32, conduction paths for the control element 61, the drive element 62 and the semiconductor element A10 to perform predetermined functions.

As shown in FIGS. 9 and 13, the first wires 41 are conductively bonded to the first electrodes 121 of the semiconductor element A10 and the electrodes 611 of the control element 61. Thus, the control element 61 and the semiconductor element A10 electrically conduct to each other. The first wires 41 are arranged along the third direction y. The composition of the first wires 41 includes gold (Au).

As shown in FIGS. 9 and 13, the second wires 42 are conductively bonded to the second electrodes 122 of the semiconductor element A10 and the electrodes 612 of the control element 62. Thus, the drive element 62 and the semiconductor element A10 electrically conduct to each other. The second wires 42 are arranged along the third direction y. In the semiconductor device B10, the second wires 42 extend across the gap between the first pad portion 211 of the first die pad 21 and the second pad portion 221 of the second die pad 22. The composition of the second wires 42 includes gold.

As shown in FIGS. 9 and 13, some of the third wires 43 are conductively bonded to the electrodes 611 of the control element 61 and the covered portions 311 of the first terminals 31. Thus, at least one of the first terminals 31 electrically conducts to the control element 61. Further, at least one of the third wires 43 is conductively bonded to one of the electrodes 611 and one of the covered portions 212A of the two first suspension lead portions 212 of the first die pad 21. Thus, at least one of the two first suspension lead portions 212 electrically conducts to the control element 61. With such a configuration, at least one of the two first suspension lead portions 212 provides a ground terminal of the control element 61. The composition of the third wires 43 includes gold. Alternatively, the composition of the first wires 41 may include copper.

As shown in FIGS. 9 and 13, some of the fourth wires 44 are conductively bonded to the electrodes 621 of the drive element 62 and the covered portions 321 of the second terminals 32. Thus, at least one of the second terminals 32 electrically conducts to the drive element 62. Further, at least one of the fourth wires 44 is conductively bonded to one of the electrodes 621 and one of the covered portions 222A of the two second suspension lead portions 222 of the second die pad 22. Thus, at least one of the two second suspension lead portions 222 electrically conducts to the drive element 62. With such a configuration, at least one of the two second suspension lead portions 222 provides a ground terminal of the drive element 62. The composition of the fourth wires 44 includes gold. Alternatively, the composition of the fourth wires 44 may include copper.

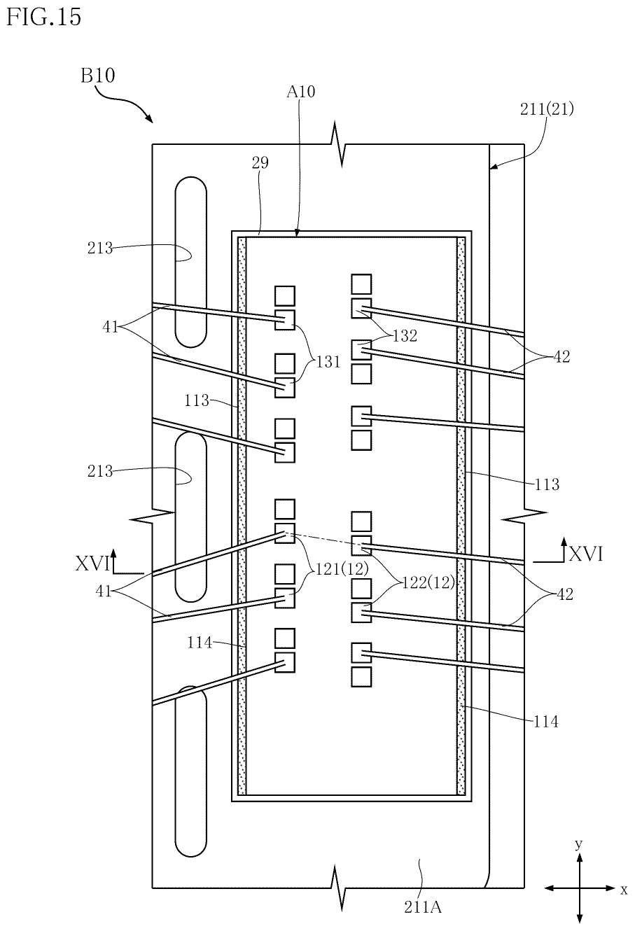

As shown in FIG. 15, the first wires 41 extend across one of the two first side surfaces 113 of the main body 11 and one of the two second side surfaces 114 of the main body 11 that is connected to that first side surface. The second wires 42 extend across the other one of the two first side surfaces 113 and the other one of the two second side surfaces 114 that is connected to that first side surface.

As shown in FIG. 8, the sealing resin 50 covers the control element 61, the drive element 62, the semiconductor element A10, and at least a part of each of the first die pad 21, the second die pad 22, the first terminals 31 and the second terminals 32. The sealing resin 50 also covers the first wires 41, the second wires 42, the third wires 43, and the fourth wires 44. The sealing resin 50 is an insulator. The sealing resin 50 is made of a material containing, for example, an epoxy resin. The sealing resin 50 is rectangular as viewed in the first direction z.

As shown in FIGS. 10 to 12, the sealing resin 50 has a top surface 51, a bottom surface 52, two first side surfaces 53, and two second side surfaces 54.

As shown in FIGS. 10 to 12, the top surface 51 and the bottom surface 52 are spaced apart from each other in the first direction z. The top surface 51 and the bottom surface 52 face away from each other in the first direction z. Each of the top surface 51 and the bottom surface 52 is generally flat.

As shown in FIGS. 10 to 12, the two first side surfaces 53 are connected to the top surface 51 and the bottom surface 52 and spaced apart from each other in the second direction x. The exposed portions 212B of the two first suspension lead portions 212 of the first die pad 21 and the exposed portions 312 of the first terminals 31 are exposed from one of the two first side surfaces 53 that is located on one side in the second direction x. The exposed portions 212B of the two second suspension lead portions 222 of the second die pad 22 and the exposed portions 322 of the second terminals 32 are exposed from the other one of the two first side surfaces 53 that is located on the other side in the second direction x.

As shown in FIGS. 10 to 12, each of the two first side surfaces 53 includes a first upper portion 531, a first lower portion 532, and a first intermediate portion 533. The first upper portion 531 is connected to the top surface 51 on one side in the first direction z and connected to the first intermediate portion 533 on the other side in the first direction z. The first upper portion 531 is inclined with respect to the top surface 51. The first lower portion 532 is connected to the bottom surface 52 on one side in the first direction z and connected to the first intermediate portion 533 on the other side in the first direction z. The first lower portion 532 is inclined with respect to the bottom surface 52. The first intermediate portion 533 is connected to the first upper portion 531 on one side in the first direction z and connected to the first lower portion 532 on the other side in the first direction z. The in-plane direction of the first intermediate portion 533 is defined by the first direction z and the third direction y. The first intermediate portion 533 is located outside the top surface 51 and the bottom surface 52 as viewed in the first direction z. The exposed portions 212B of the two first suspension lead portions 212 of the first die pad 21, the exposed portions 212B of the two second suspension lead portions 222 of the second die pad 22, the exposed portions 312 of the first terminals 31, and the exposed portions 322 of the second terminals 32 are exposed from the first intermediate portions 533 of the two first side surfaces 53.

As shown in FIGS. 10 to 12, the two second side surfaces 54 are connected to the top surface 51 and the bottom surface 52 and spaced apart from each other in the third direction y. As shown in FIG. 8, the first die pad 21, the second die pad 22, the first terminals 31, and the second terminals 32 are spaced apart from the two second side surfaces 54.

As shown in FIGS. 10 to 12, each of the two second side surfaces 54 includes a second upper portion 541, a second lower portion 542, and a second intermediate portion 543. The second upper portion 541 is connected to the top surface 51 on one side in the first direction z and connected to the second intermediate portion 543 on the other side in the first direction z. The second upper portion 541 is inclined with respect to the top surface 51. The second lower portion 542 is connected to the bottom surface 52 on one side in the first direction z and connected to the second intermediate portion 543 on the other side in the first direction z. The second lower portion 542 is inclined with respect to the bottom surface 52. The second intermediate portion 543 is connected to the second upper portion 541 on one side in the first direction z and connected to the second lower portion 542 on the other side in the first direction z. The in-plane direction of the second intermediate portion 543 is defined by the first direction z and the third direction y. The second intermediate portion 543 is located outside the top surface 51 and the bottom surface 52 as viewed in the first direction z.

In the motor driver circuit of an inverter device a half-bridge circuit to include a low-side (low-potential side) switching element and a high-side (high-potential side) switching element is formed in general. An example in which these switching elements are MOSFETs is described below. In the low-side switching element, the reference potentials of the source of the switching element and the gate driver that drives the switching element are both ground. On the other hand, in the high-side switching element, the reference potentials of the source of the switching element and the gate driver that drives the switching element both correspond to the potential at the output node of the half-bridge circuit. Because the potential at the output node changes in response to the operation of the high-side switching element and the low-side switching element, the reference potential of the gate driver that drives the high-side switching element changes. When the high-side switching element is ON, the reference potential is equivalent to the voltage applied to the drain of the high-side switching element (e.g., 600 V or higher). In semiconductor device B10, the ground of the control element 61 and the ground of the drive element 62 are separated. Thus, when the semiconductor device B10 is used as a gate driver for driving the high-side switching element, a voltage equivalent to the voltage applied to the drain of the high-side switching element is transiently applied to the ground of the drive element 62.

### Second Embodiment (Semiconductor Device B20)

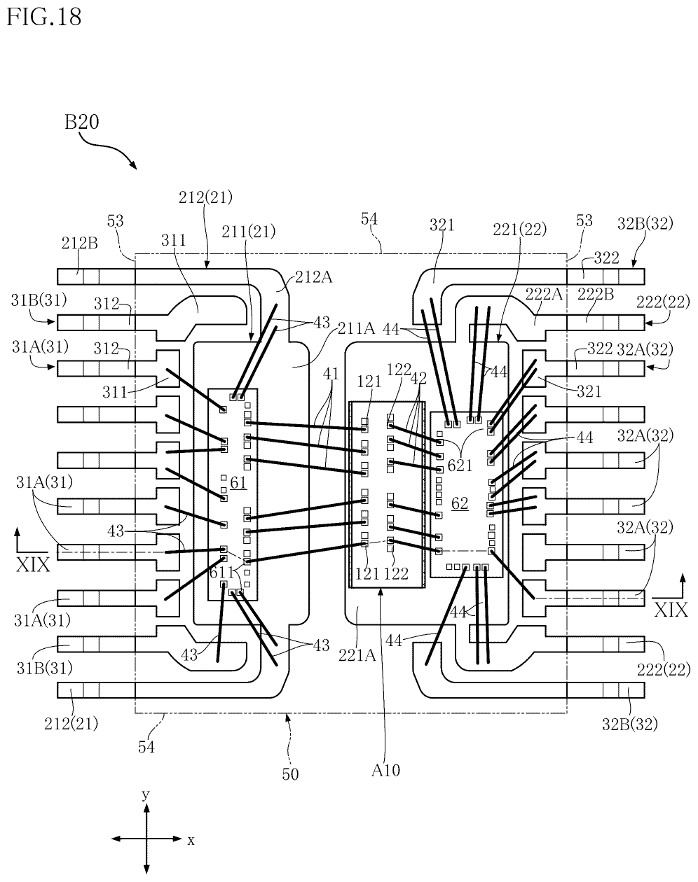

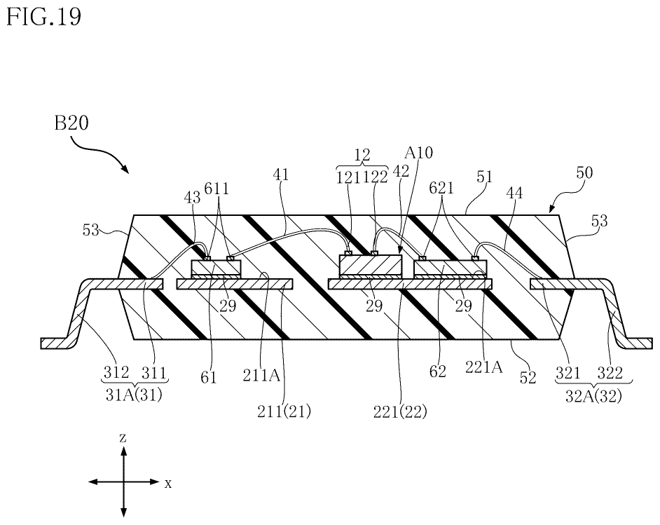

A semiconductor device B20 according to a second embodiment of the present disclosure will be described based on FIGS. 18 and 19. In these figures, the elements that are identical or similar to those of the semiconductor device B10 described above are denoted by the same reference signs, and the descriptions thereof are omitted. In FIG. 18, the sealing resin 50 is shown in its outline only for the convenience of understanding. In FIG. 18, the outline of the sealing resin 50 is shown by imaginary lines.

The semiconductor device B20 differs from the semiconductor device B10 in the configuration of the semiconductor element A10.

As shown in FIGS. 18 and 19, the semiconductor element A10 is mounted on the second mount surface 221A of the second pad portion 221 of the second die pad 22. As in the semiconductor device B10, the main body 11 of the semiconductor element A10 is bonded to the second mount surface 221A via a bonding layer 29. In the semiconductor device B20 as well, the bonding layer 29 is in contact with the first side surface 113 of the main body 11. In the semiconductor device B20, therefore, the first wires 41 extend across the gap between the first pad portion 211 of the first die pad 21 and the second pad portion 221. In this way, the semiconductor element A10 can be mounted on the second pad portion 221 also in the case where the potential of the second pad portion 221 is higher than the potential of the first pad portion 211.

Next, the effects of the semiconductor element A10 and the semiconductor device B10 will be described.

The main body 11 of the semiconductor element A10 has a first side surface 113 facing in the second direction x and a second side surface 114 connected to the first edge 113A of the first side surface 113. The second side surface 114 is located between the first side surface 113 and the obverse surface 111 of the main body 11 in the first direction z. The second side surface 114 overlaps with the reverse surface 112 of the main body 11 as viewed in the first direction z. As shown in FIG. 16, when the semiconductor element A10 is mounted on the first die pad 21 in the manufacture of the semiconductor device B10, the bonding layer 29 rising from the periphery of the reverse surface 112 onto the first side surface 113 may reach the first edge 113A. With the present configuration, however, the surface tension of the bonding layer 29 at the first edge 113A makes it difficult for the bonding layer 29 to rise beyond the first edge 113A to the side on which the obverse surface 111 is located.

Further, in the main body 11 of the semiconductor element A10, the surface roughness of the first side surface 113 differs from that of the second side surface 114. Such a configuration effectively suppresses the rising of the bonding layer 29 in the semiconductor element A10. For example, when the surface roughness of the first side surface 113 is greater than that of the second side surface 114 as in the semiconductor element A10, the rising of the bonding layer 29 can be stopped on the first side surface 113 before the bonding layer 29 reaches the first edge 113A. Conversely, when the surface roughness of the second side surface 114 is greater than that of the first side surface 113 as in the semiconductor element A11, the rising of the bonding layer 29 can be stopped on the second side surface 114 as shown in FIG. 17. Thus, with the above-described configuration and the present configuration, the semiconductor element A10 is capable of suppressing the rising of the bonding layer 29.

When the surface roughness of the second side surface 114 is smaller than that of the first side surface 113, it is preferable that the dimension h1 of the first side surface 113 in the first direction z is greater than the dimension h2 of the second side surface 114 in the first direction z to reliably stop the rising of the bonding layer 29 on the first side surface 113. When such a configuration is employed, the surface roughness of the first blade 81 shown in FIG. 4 is set smaller than the surface roughness of the second blade 82 shown in FIG. 5. This prevents defects from occurring in the obverse surface 111 of the main body 11.

When the surface roughness of the second side surface 114 is greater than that of the first side surface 113, it is preferable that the dimension h2 of the second side surface 114 in the first direction z is greater than the dimension h1 of the first side surface 113 in the first direction z to reliably stop the rising of the bonding layer 29 on the second side surface 114.

In the semiconductor device B10, the first wires 41 and the second wires 42 extend across the first side surfaces 113 and the second side surfaces 114. Such a configuration prevents the bonding layer 29 rising on the semiconductor element A10 from adhering to the first wires 41 and the second wires 42.

In the semiconductor device B10, a part of each of the first die pad 21, the second die pad 22, the first terminals 31 and the second terminals 32 is exposed from one of the two first side surfaces 53. Such a configuration is provided by exposing the two first suspension lead portions 212 of the first die pad 21 from one side of the sealing resin 50 in the second direction x and exposing the two second suspension lead portions 222 of the second die pad 22 from the other side of the sealing resin 50 in the second direction x. In this case, the first die pad 21, the second die pad 22, the first terminals 31, and the second terminals 32 are spaced apart from the two second side surfaces 54 of the sealing resin 50. Thus, none of the first die pad 21, the second die pad 22, the first terminals 31, and the second terminals 32 are exposed from the two second side surfaces 54. Such a configuration contributes to improving the dielectric strength of the semiconductor device B10.

In the semiconductor device B10, the first pad portion 211 of the first die pad 21, which has a greater area than the second pad portion 221 of the second die pad 22, is formed with a plurality of through-holes 213. Thus, in the manufacture of the semiconductor device B10, the fluidized sealing resin 50 passes through the through holes 213, so that insufficient filling of the sealing resin 50 is prevented. Therefore, the formation of voids in the sealing resin 50 is effectively suppressed. This contributes to improving the dielectric strength of the semiconductor device B10.

### Second Embodiment (Semiconductor Element A20)

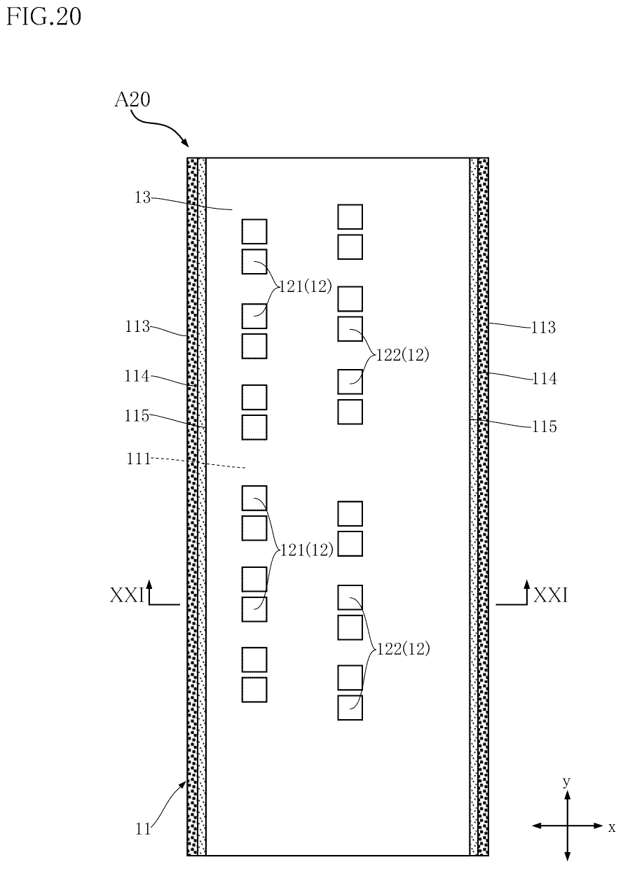

A semiconductor element A20 according to a second embodiment of the present disclosure will be described based on FIGS. 20 to 23. In these figures, the elements that are identical or similar to those of the semiconductor element A10 described above are denoted by the same reference signs, and the descriptions thereof are omitted.

The semiconductor element A20 differs from the semiconductor element A10 in the configuration of the main body 11.

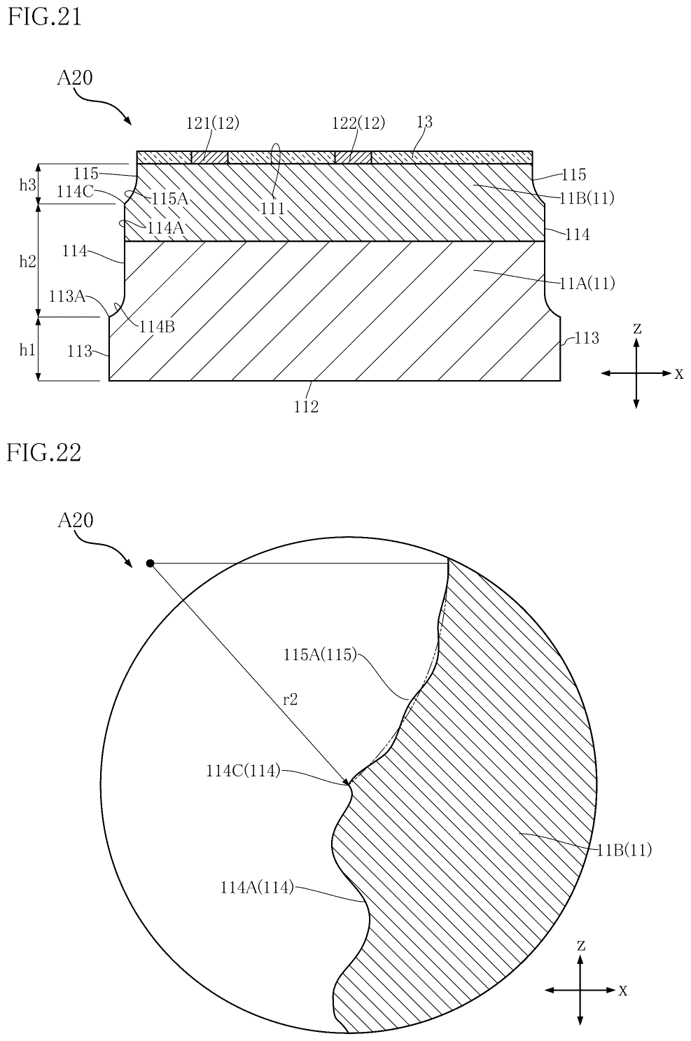

As shown in FIGS. 20 and 21, the main body 11 has two third side surfaces 115. The two third side surfaces 115 face away from each other in the second direction x. The two third side surfaces 115 are connected to the two second side surfaces 114, respectively. Each of the two third side surfaces 115 extends in the third direction y. Only one of the two third side surfaces 113 that is connected to one of the two second side surfaces 114 will be described below.

As shown in FIG. 21, the second side surface 114 has a second edge 114C that is farthest from the reverse surface 112. The third side surface 115 is connected to the second edge 114C. The third side surface 115 is located between the second side surface 114 and the obverse surface 111 of the main body 11 in the first direction z. The third side surface 115 overlaps with the reverse surface 112 of the main body 11 as viewed in the first direction z.

As shown in FIG. 21, the third side surface 115 includes a third region 115A. The third region 115A is connected to the second edge 114C. The third region 115A is curved toward the reverse surface 112 of the main body 11.

In the semiconductor element A20, the dimension h1 of the first side surface 113 in the first direction z is smaller than the dimension h2 of the second side surface 114 in the first direction z as shown in FIG. 21. The dimension h3 of the third side surface 115 in the first direction z is smaller than the dimension h2.

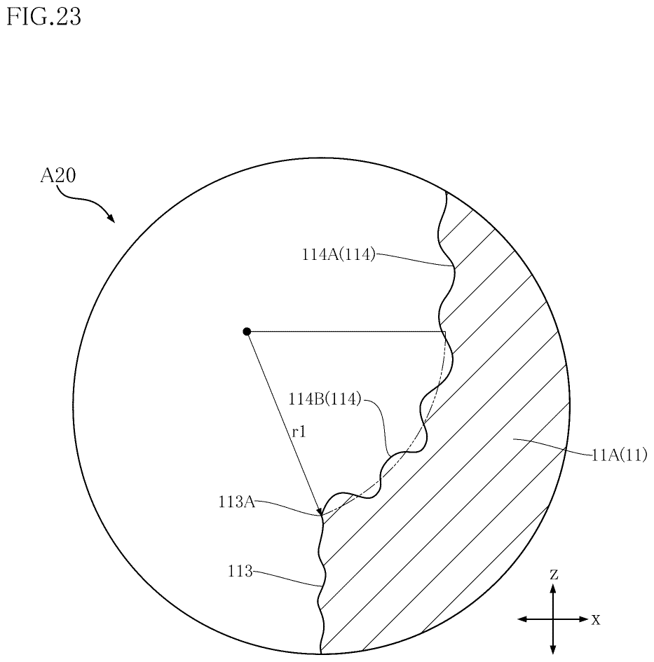

As shown in FIG. 22, the surface roughness of the third side surface 115 is smaller than that of the second side surface 114. The surface roughness of the third side surface 115 is greater than that of the reverse surface 112. As shown in FIG. 23, the surface roughness of the second side surface 114 is greater than that of the first side surface 113.

Assuming that the surface roughness of the third region 115A is zero (two-dot chain lines shown in FIG. 22) in the cross-section in which the first direction z and the second direction x define the in-plane direction, the third region 115A forms a curved surface with a radius of curvature r2, as shown in FIG. 22. The radius of curvature r2 is greater than the radius of curvature r1 shown in FIG. 23.

### Variation (Semiconductor Element A21):

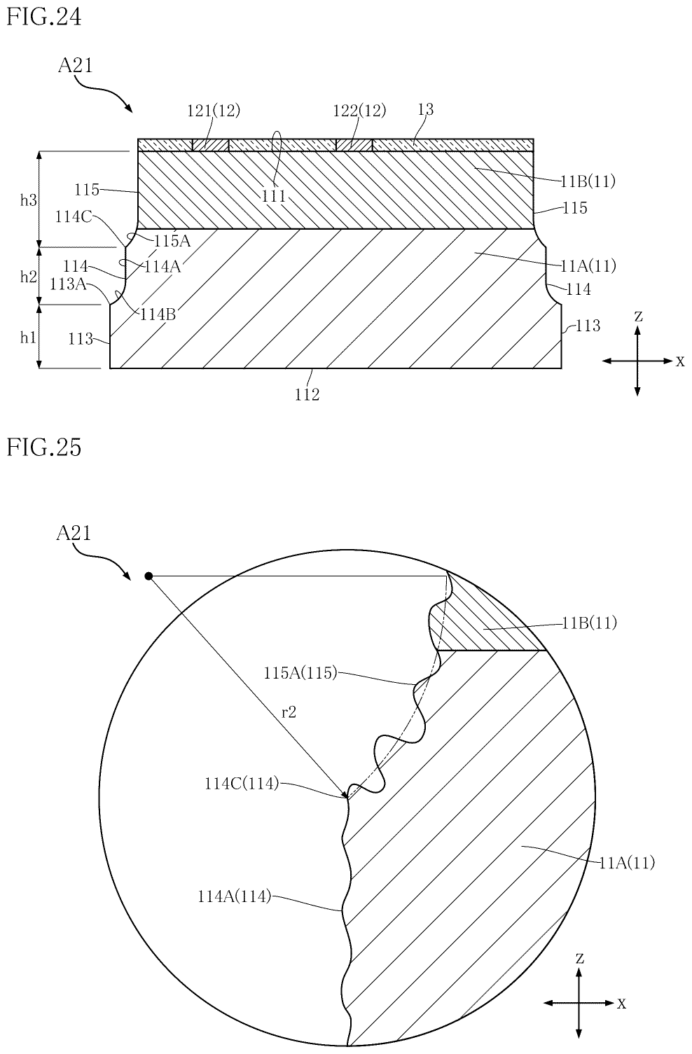

Next, a semiconductor element A21, which is a variation of the semiconductor element A20, will be described based on FIGS. 24 and 25. The sectional position of FIG. 24 corresponds to (or generally corresponds to) the sectional position of FIG. 21.

As shown in FIG. 24, the semiconductor element A21 differs from the semiconductor element A20 in the configurations of the second side surface 114 and the third side surface 115. The dimension h3 of the third side surface 115 in the first direction z is greater than the dimension h2 of the second side surface 114 in the first direction z.

As shown in FIG. 25, the surface roughness of the third side surface 115 is greater than the surface roughness of the second side surface 114. In the semiconductor element A21 as well, assuming that the surface roughness of the third region 115A is zero (two-dot chain lines shown in FIG. 25) in the cross-section in which the first direction z and the second direction x define the in-plane direction, the third region 115A forms a curved surface with a radius of curvature r2.

Next, the effects of the semiconductor element A20 will be described.

The main body 11 of the semiconductor element A20 has a first side surface 113 facing in the second direction x and a second side surface 114 connected to the first edge 113A of the first side surface 113. The second side surface 114 is located between the first side surface 113 and the obverse surface 111 of the main body 11 in the first direction z. The second side surface 114 overlaps with the reverse surface 112 of the main body 11 as viewed in the first direction z. The surface roughness of the first side surface 113 differs from that of the second side surface 114. Thus, with the present configuration, the semiconductor element A20 is also capable of suppressing the rising of the bonding layer 29. Further, the semiconductor element A20 has a configuration in common with the semiconductor element A10, thereby achieving the same effects as the semiconductor element A10.

In the semiconductor element A20, the main body 11 has a third side surface 115 connected to the second edge 114C of the second side surface 114. The third side surface 115 is located between the second side surface 114 and the obverse surface 111 of the main body 11 in the first direction z. The third side surface 115 overlaps with the reverse surface 112 of the main body 11 as viewed in the first direction z. With the present configuration, the rising of the bonding layer 29 onto the semiconductor element A10 can be suppressed at two locations, i.e., the first edge 113A of the first side surface 113 and the second edge 114C of the second side surface 114.

### Third Embodiment (Semiconductor Element A30)

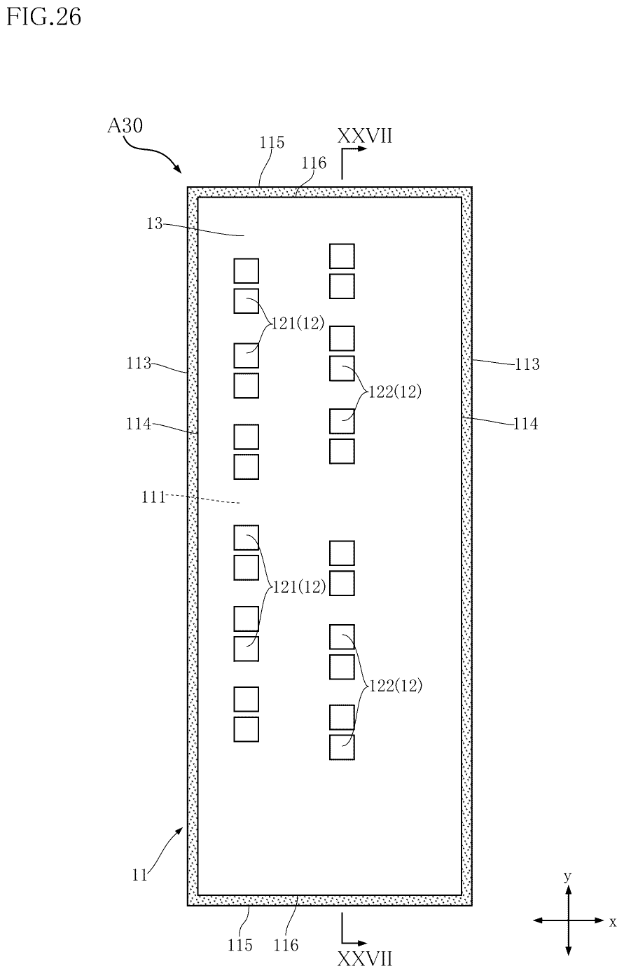

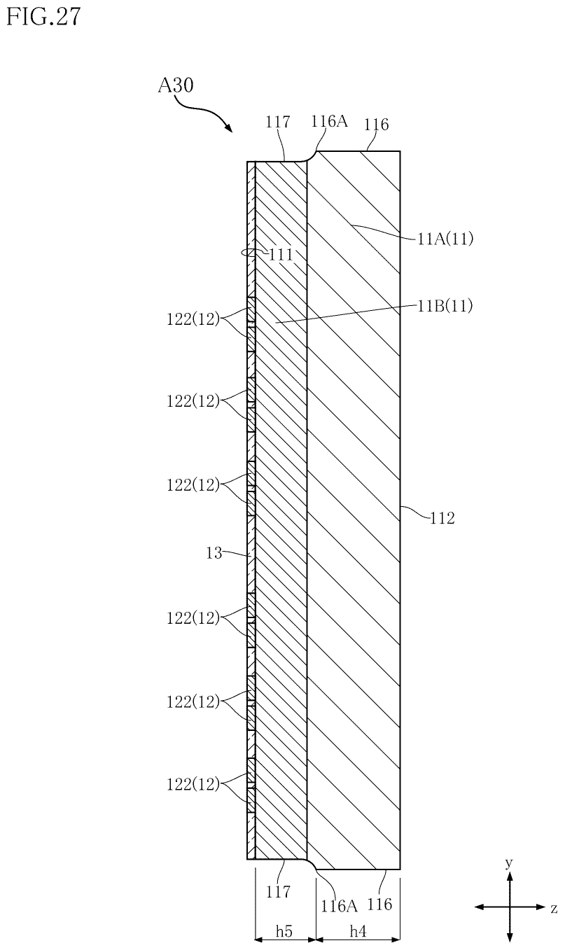

A semiconductor element A30 according to a third embodiment of the present disclosure will be described based on FIGS. 26 and 27. In these figures, the elements that are identical or similar to those of the semiconductor element A10 described above are denoted by the same reference signs, and the descriptions thereof are omitted.

The semiconductor element A30 differs from the semiconductor element A10 in the configuration of the main body 11.

As shown in FIGS. 26 and 27, the main body 11 has two fourth side surfaces 116 and two fifth side surfaces 117. The two fourth side surfaces 116 face away from each other in the third direction y. The two fifth side surfaces 117 face away from each other in the third direction y. The two fifth side surfaces 117 are connected to the two fourth side surfaces 116, respectively. Each of the two fourth side surfaces 116 and the two fifth side surfaces 117 extends in the third direction y.

As shown in FIG. 27, each of the two fourth side surfaces 116 has a third edge 116A that is farthest from the reverse surface 112. The two fifth side surfaces 117 are connected to the third edges 116A of the two fourth side surfaces 116, respectively. The two fifth side surfaces 117 are located between the two fourth side surfaces 116 and the obverse surface 111 of the main body 11 in the first direction z. The two fifth side surfaces 117 overlap with the reverse surface 112 of the main body 11 as viewed in the first direction z.

As shown in FIG. 27, the dimension h4 of each of the two fourth side surfaces 116 in the first direction z is equal to the dimension h1 of the first side surfaces 113 in the first direction z shown in FIG. 2. The dimension h5 of each of the two fifth side surfaces 117 in the first direction z is equal to the dimension h2 of the second side surfaces 114 in the first direction z shown in FIG. 2. Therefore, the dimension h4 is greater than the dimension h5.

Because the main body 11 has two first side surfaces 113, two second side surfaces 114, two fourth side surfaces 116 and two fifth side surfaces 117, the periphery of the obverse surface 111 of the main body 11 is surrounded by the reverse surface 112 of the main body 11.

Next, the effects of the semiconductor element A30 will be described.

The main body 11 of the semiconductor element A30 has a first side surface 113 facing in the second direction x and a second side surface 114 connected to the first edge 113A of the first side surface 113. The second side surface 114 is located between the first side surface 113 and the obverse surface 111 of the main body 11 in the first direction z. The second side surface 114 overlaps with the reverse surface 112 of the main body 11 as viewed in the first direction z. The surface roughness of the first side surface 113 differs from that of the second side surface 114. Thus, with the present configuration, the semiconductor element A30 is also capable of suppressing the rising of the bonding layer 29. Further, the semiconductor element A30 has a configuration in common with the semiconductor element A10, thereby achieving the same effects as the semiconductor element A10.

The present disclosure is not limited to the above-described embodiments. Various modifications in design may be made freely in the specific structure of each part of the present disclosure.

The present disclosure includes embodiments described in the following clauses.

### Clause 1

A semiconductor element comprising:
a main body including an obverse surface and a reverse surface facing away from each other in a first direction; and
a plurality of electrodes disposed on the obverse surface and electrically conducting to the main body, wherein
the main body includes a first side surface facing in a second direction orthogonal to the first direction,
the first side surface includes a first edge that is farthest from the reverse surface,
the main body includes a second side surface connected to the first edge and located between the first side surface and the obverse surface in the first direction,
the second side surface overlaps with the reverse surface as viewed in the first direction, and
a surface roughness of the first side surface differs from a surface roughness of the second side surface.

### Clause 2

The semiconductor element according to clause 1, wherein a dimension of the first side surface in the first direction is greater than a dimension of the second side surface in the first direction, and
the surface roughness of the second side surface is smaller than the surface roughness of the first side surface.

### Clause 3

The semiconductor element according to clause 2, wherein the dimension of the first side surface in the first direction is equal to or greater than 50% of a dimension of the main body in the first direction.

### Clause 4

The semiconductor element according to clause 1, wherein a dimension of the second side surface in the first direction is greater than a dimension of the first side surface in the first direction, and
the surface roughness of the second side surface is greater than the surface roughness of the first side surface.

### Clause 5

The semiconductor element according to any one of clauses 1 to 4, wherein the second side surface includes a first region facing in the second direction and a second region connected to the first edge and the first region, and
the second region is curved toward the reverse surface.

### Clause 6

The semiconductor element according to any one of clauses 1 to 5, wherein the second side surface includes a second edge that is farthest from the reverse surface,
the main body includes a third side surface connected to the second edge and located between the second side surface and the obverse surface in the first direction, and
the third side surface overlaps with the reverse surface as viewed in the first direction.

### Clause 7

The semiconductor element according to clause 6, wherein a dimension of the second side surface in the first direction is greater than a dimension of the third side surface in the first direction, and
a surface roughness of the third side surface is smaller than the surface roughness of the second side surface.

### Clause 8

The semiconductor element according to clause 6, wherein a dimension of the third side surface in the first direction is greater than a dimension of the second side surface in the first direction, and
a surface roughness of the third side surface is greater than the surface roughness of the second side surface.

### Clause 9

The semiconductor element according to any one of clauses 1 to 8, wherein the obverse surface is surrounded by a periphery of the reverse surface as viewed in the first direction.

### Clause 10

The semiconductor element according to any one of clauses 1 to 9, wherein a dimension of the main body in a third direction orthogonal to the first direction and the second direction is greater than a dimension of the main body in the second direction.

### Clause 11

A semiconductor device comprising:
the semiconductor element as set forth in any one of clauses 1 to 10;
a first die pad facing the reverse surface;
a bonding layer that bonds the first die pad and the semiconductor element; and
a plurality of wires conductively bonded to the plurality of electrodes, respectively, wherein
the plurality of wires extend across the first side surface and the second side surface, and
the bonding layer is in contact with the first side surface.

### Clause 12

The semiconductor device according to clause 11, wherein the bonding layer is in contact with the first edge.

### Clause 13

The semiconductor device according to clause 11 or 12, further comprising:
a control element;
a second die pad spaced apart from the first die pad; and
a drive element mounted on one of the first die pad and the second die pad, wherein
the plurality of electrodes include a plurality of first electrodes and a plurality of second electrodes,
the plurality of wires include a plurality of first wires conductively bonded to the plurality of first electrodes, respectively, and a plurality of second wires conductively bonded to the plurality of second electrodes, respectively,
the plurality of first wires are conductively bonded to the drive element, and
the plurality of second wire are conductively bonded to the control element.

### Clause 14

The semiconductor device according to clause 13, wherein the control element is mounted on the first die pad, and
the drive element is mounted on the second die pad.

### Clause 15

The semiconductor device according to clause 14, wherein the control element is located opposite to the drive element with respect to the semiconductor element in the second direction.

### Clause 16

The semiconductor device according to any one of clauses 13 to 15, further comprising a sealing resin covering the semiconductor element, the control element, the drive element, and the plurality of wires.

### Clause 17

The semiconductor device according to clause 16, further comprising: a plurality of first terminals electrically conducting to the control element; and
a plurality of second terminals electrically conducting to the drive element, wherein
a part of each of the plurality of first terminals and a part of each of the plurality of second terminals are covered with the sealing resin.

### REFERENCE NUMERALS

A10, A20, A30: Semiconductor element
B10, B20: Semiconductor device
11: Main body 11A: Semiconductor substrate
11B: Semiconductor layer 111: Obverse surface
112: Reverse surface 113: First side surface
113A: First edge 114: Second side surface
114A: First region 114B: Second region
114C: Second edge 115: Third side surface
115A: Third region 116: Fourth side surface
116A: Third edge 117: Fifth side surface
12: Electrode 121: First electrode
122: Second electrode 13: Passivation film
21: First die pad 211: First pad portion
211A: First mounting surface 212: First suspension lead portion
212A: Covered portion 212B: Exposed portion
213: Through-hole 22: Second die pad
221: Second pad portion 221A: Second mount surface
222: Second suspension lead portion 222A: Covered portion
222B: Exposed portion 29: Bonding layer
31: First terminal 31A: First intermediate terminal
31B: First-side terminal 311: Covered portion
312: Exposed portion 32: Second terminal
32A: Second intermediate terminal 32B: Second-side terminal
321: Covered portion 322: Exposed portion
41: First wire 42: Second wire
43: Third wire 44: Fourth wire
50: Sealing resin 51: Top surface
52: Bottom surface 53: First side surface
531: First upper portion 532: First lower portion
533: First intermediate portion 54: Second side surface
541: Second upper portion 542: Second lower portion
543: Second intermediate portion 61: Control element
611: Electrode 62: Drive element
621: Electrode 80: Tape
81: First blade 82: Second blade
83: Groove z: First direction
x: Second direction y: Third direction

1. A semiconductor element comprising:
a main body including an obverse surface and a reverse surface facing away from each other in a first direction; and
a plurality of electrodes disposed on the obverse surface and electrically conducting to the main body, wherein
the main body includes a first side surface facing in a second direction orthogonal to the first direction,
the first side surface includes a first edge that is farthest from the reverse surface,
the main body includes a second side surface connected to the first edge and located between the first side surface and the obverse surface in the first direction,
the second side surface overlaps with the reverse surface as viewed in the first direction, and
a surface roughness of the first side surface differs from a surface roughness of the second side surface.

2. The semiconductor element according to claim 1, wherein a dimension of the first side surface in the first direction is greater than a dimension of the second side surface in the first direction, and
the surface roughness of the second side surface is smaller than the surface roughness of the first side surface.

3. The semiconductor element according to claim 2, wherein the dimension of the first side surface in the first direction is equal to or greater than 50% of a dimension of the main body in the first direction.

4. The semiconductor element according to claim 1, wherein a dimension of the second side surface in the first direction is greater than a dimension of the first side surface in the first direction, and
the surface roughness of the second side surface is greater than the surface roughness of the first side surface.

5. The semiconductor element according to claim 1, wherein the second side surface includes a first region facing in the second direction and a second region connected to the first edge and the first region, and
the second region is curved toward the reverse surface.

6. The semiconductor element according to claim 1, wherein the second side surface includes a second edge that is farthest from the reverse surface,
the main body includes a third side surface connected to the second edge and located between the second side surface and the obverse surface in the first direction, and
the third side surface overlaps with the reverse surface as viewed in the first direction.

7. The semiconductor element according to claim 6, wherein a dimension of the second side surface in the first direction is greater than a dimension of the third side surface in the first direction, and
a surface roughness of the third side surface is smaller than the surface roughness of the second side surface.

8. The semiconductor element according to claim 6, wherein a dimension of the third side surface in the first direction is greater than a dimension of the second side surface in the first direction, and
a surface roughness of the third side surface is greater than the surface roughness of the second side surface.

9. The semiconductor element according to claim 1, wherein the obverse surface is surrounded by a periphery of the reverse surface as viewed in the first direction.

10. The semiconductor element according to claim 1, wherein a dimension of the main body in a third direction orthogonal to the first direction and the second direction is greater than a dimension of the main body in the second direction.

11. A semiconductor device comprising:
the semiconductor element as set forth in claim 1;
a first die pad facing the reverse surface;
a bonding layer that bonds the first die pad and the semiconductor element; and
a plurality of wires conductively bonded to the plurality of electrodes, respectively, wherein
the plurality of wires extend across the first side surface and the second side surface, and
the bonding layer is in contact with the first side surface.

12. The semiconductor device according to claim 11, wherein the bonding layer is in contact with the first edge.

13. The semiconductor device according to claim 11, further comprising:
a control element;
a second die pad spaced apart from the first die pad; and
a drive element mounted on one of the first die pad and the second die pad, wherein
the plurality of electrodes include a plurality of first electrodes and a plurality of second electrodes,
the plurality of wires include a plurality of first wires conductively bonded to the plurality of first electrodes, respectively, and a plurality of second wires conductively bonded to the plurality of second electrodes, respectively,
the plurality of first wires are conductively bonded to the drive element, and
the plurality of second wire are conductively bonded to the control element.

14. The semiconductor device according to claim 13, wherein the control element is mounted on the first die pad, and
the drive element is mounted on the second die pad.

15. The semiconductor device according to claim 14, wherein the control element is located opposite to the drive element with respect to the semiconductor element in the second direction.

16. The semiconductor device according to claim 13, further comprising a sealing resin covering the semiconductor element, the control element, the drive element, and the plurality of wires.

17. The semiconductor device according to claim 16, further comprising: a plurality of first terminals electrically conducting to the control element; and
a plurality of second terminals electrically conducting to the drive element, wherein
a part of each of the plurality of first terminals and a part of each of the plurality of second terminals are covered with the sealing resin.
